(19) United States
(12) Patent Application Publication
(10) Pub. No.: US 2016/0290103 A1
(43) Pub. Date: Oct. 6, 2016

(54) VAPOR-DEPOSITING METAL OXIDE ON SURFACES FOR WELLS OR PIPELINES TO REDUCE SCALE

(71) Applicant: HALLIBURTON ENERGY SERVICES, INC., Houston, TX (US)

(72) Inventors: Lucas Kurtis Fontenelle, Houston, TX (US); Nathan Carl Schultheiss, Kingwood, TX (US); Jimmie Dean Weaver, JR., Duncan, OK (US)

(73) Assignee: Halliburton Energy Services, Inc., Houston, TX (US)

(21) Appl. No.: 15/035,061

(22) PCT Filed: Dec. 6, 2013
(86) PCT No.: PCT/US2013/073499

§ 371 Date: May 6, 2016

(51) Int. Cl. E21B 37/06; C23C 14/24; F16L 58/08; C23C 14/22

(52) U.S. Cl. CPC E21B 37/06; C23C 14/228; C23C 14/24; F16L 58/08

(57) ABSTRACT

Methods of protecting a surface of a metallic body against scale formation in a well or pipeline including the steps of: vapor depositing a source material comprising a metal oxide onto the surface of the metallic body; and positioning the metallic body in a wellbore of a well or to form a portion of a pipeline.

### CROSS-REFERENCE TO RELATED APPLICATIONS

Not applicable.

### TECHNICAL FIELD

The disclosure is in the field of producing oil or gas from subterranean formations or the pipeline transmission of oil or gas. More specifically, the disclosure generally relates to devices, methods, and systems for use in wells or pipelines to reduce scale-formation.

### BACKGROUND

Relatively high concentrations of scale-forming ions in a fluid in a well can lead to damage to wellbore servicing equipment, for example, through corrosion or the formation of scale (such as calcite scale, barite scale, or magnesium carbonate scale) on the inner flow surfaces of such wellbore servicing equipment. Similar problems can occur on the inner flow surfaces of pipelines. Accordingly, there is a need for reducing the accumulation of scale on such surfaces.

### GENERAL DESCRIPTION OF EMBODIMENTS

In various embodiments, methods of protecting a surface of a metallic body against scale formation in a well are provided, the methods comprising: vapor depositing a source material comprising a metal oxide onto the surface of the metallic body; and positioning the metallic body in a wellbore of a well. Such a method can additionally include, for example, flowing a fluid across the surface of the metallic body in the well, wherein the fluid comprises scale-forming ions.

In various embodiments, well systems are provided, including a wellbore; and a metallic body positioned in the wellbore, wherein a surface of the metallic body has a coating produced by vapor depositing a source material comprising a metal oxide onto the surface. Such a method can additionally include, for example, a fluid in the wellbore, wherein the fluid comprises scale-forming ions.

In various embodiments, methods of protecting a surface of a metallic body against scale formation in a pipeline, the method comprising: vapor depositing a source material comprising a metal oxide onto the surface of the metallic body; and positioning the metallic body to form a portion of a pipeline. Such a method can additionally include, for example, flowing a fluid across the surface of the metallic body in the pipeline, wherein the fluid comprises scale-forming ions.

In various embodiments, pipeline systems are provided, the pipeline system comprising: a metallic body positioned to form a portion of the pipeline, wherein a surface of the metallic body exposed to the interior fluid flowpath of the pipeline has a coating produced by vapor depositing a source material comprising a metal oxide onto the surface. Such a method can additionally include, for example, a fluid in the pipeline, wherein the fluid comprises scale-forming ions.

These and other embodiments of the disclosure will be apparent to one skilled in the art upon reading the following detailed description. While the disclosure is susceptible to various modifications and alternative forms, specific embodiments thereof will be described in detail and shown by way of example. It should be understood, however, that it is not intended to limit the disclosure to the particular forms disclosed.

### BRIEF DESCRIPTION OF THE DRAWING

The accompanying drawing is incorporated into the specification to help illustrate examples according to a presently preferred embodiment of the disclosure. It should be understood that the figures of the drawing are not necessarily to scale.

FIG. 1 is a schematic illustration of a well operating environment and system.

FIG. 2 is an illustration of an offshore well site operatively connected to a pipeline for transmission of produced oil or gas.

FIG. 3 is a schematic illustration of a vapor-deposition furnace and system.

FIG. 4 is an cross-sectional illustration of a length of a tubular such as downhole in a well or part of a pipeline, having an inner wall surface graphically representing the various scale-precipitation processes and reduction in scale accumulation on a surface having a vapor-deposited material according to the disclosure.

### DETAILED DESCRIPTION OF PRESENTLY PREFERRED EMBODIMENTS AND BEST MODE

### Definitions and Usages

### General Interpretation

The words or terms used herein have their plain, ordinary meaning in the field of this disclosure, except to the extent explicitly and clearly defined in this disclosure or unless the specific context otherwise requires a different meaning.

If there is any conflict in the usages of a word or term in this disclosure and one or more patent(s) or other documents that may be incorporated by reference, the definitions that are consistent with this specification should be adopted.

The words “comprising,” “containing,” “including,” “having,” and all grammatical variations thereof are intended to have an open, non-limiting meaning. For example, a composition comprising a component does not exclude it from having additional components, an apparatus comprising a part does not exclude it from having additional parts, and a method having a step does not exclude it having additional steps. When such terms are used, the compositions, apparatuses, and methods that “consist essentially of” or “consist of” the specified components, parts, and steps are specifically included and disclosed. As used herein, the words “consisting essentially of,” and all grammatical variations thereof are intended to limit the scope of a claim to the specified materials or steps and those that do not materially affect the basic and novel characteristic(s) of the claimed invention.

The indefinite articles “a” or “an” mean one or more than one of the component, part, or step that the article introduces.

Each numerical value should be read once as modified by the term “about” (unless already expressly so modified), and then read again as not so modified, unless otherwise indicated in context.

Whenever a numerical range of degree or measurement with a lower limit and an upper limit is disclosed, any number and any range falling within the range is also intended to be specifically disclosed. For example, every range of values (in the form “from a to b,” or “from about a to about b,” or “from about a to b,” “from approximately a to b,” and any similar expressions, where “a” and “b” represent numerical values of degree or measurement) is to be understood to set forth every number and range encompassed within the broader range of values.

It should be understood that algebraic variables and other scientific symbols used herein are selected arbitrarily or according to convention. Other algebraic variables can be used.

Terms such as “first,” “second,” “third,” etc. may be assigned arbitrarily and are merely intended to differentiate between two or more components, parts, or steps that are otherwise similar or corresponding in nature, structure, function, or action. For example, the words “first” and “second” serve no other purpose and are not part of the name or description of the following name or descriptive terms. The mere use of the term “first” does not require that there be any “second” similar or corresponding component, part, or step. Similarly, the mere use of the word “second” does not require that there be any “first” or “third” similar or corresponding component, part, or step. Further, it is to be understood that the mere use of the term “first” does not require that the element or step be the very first in any sequence, but merely that it is at least one of the elements or steps. Similarly, the mere use of the terms “first” and “second” does not necessarily require any sequence. Accordingly, the mere use of such terms does not exclude intervening elements or steps between the “first” and “second” elements or steps, etc.

The control or controlling of a condition includes any one or more of maintaining, applying, or varying of the condition. For example, controlling the temperature of a substance can include heating, cooling, or thermally insulating the substance.

### Oil and Gas Reservoirs

In the context of production from a well, “oil” and “gas” are understood to refer to crude oil and natural gas, respectively. Oil and gas are naturally occurring hydrocarbons in certain subterranean formations.

A “subterranean formation” is a body of rock that has sufficiently distinctive characteristics and is sufficiently continuous for geologists to describe, map, and name it.

A subterranean formation having a sufficient porosity and permeability to store and transmit fluids is sometimes referred to as a “reservoir.”

A subterranean formation containing oil or gas may be located under land or under the seabed off shore. Oil and gas reservoirs are typically located in the range of a few hundred feet (shallow reservoirs) to a few tens of thousands of feet (ultra-deep reservoirs) below the surface of the land or seabed.

### Well Servicing and Fluids

To produce oil or gas from a reservoir, a wellbore is drilled into a subterranean formation, which may be the reservoir or adjacent to the reservoir. Typically, a wellbore of a well must be drilled hundreds or thousands of feet into the earth to reach a hydrocarbon-bearing formation.

Generally, well services include a wide variety of operations that may be performed in oil, gas, geothermal, or water wells, such as drilling, cementing, completion, and intervention. Well services are designed to facilitate or enhance the production of desirable fluids such as oil or gas from or through a subterranean formation. A well service usually involves introducing a fluid into a well.

A “well” includes a wellhead and at least one wellbore from the wellhead penetrating the earth. The “wellhead” is the surface termination of a wellbore, which surface may be on land or on a seabed.

A “well site” is the geographical location of a wellhead of a well. It may include related facilities, such as a tank battery, separators, compressor stations, heating or other equipment, and fluid pits. If offshore, a well site can include a platform.

The “wellbore” refers to the drilled hole, including any cased or uncased portions of the well or any other tubulars in the well. The “borehole” usually refers to the inside wellbore wall, that is, the rock surface or wall that bounds the drilled hole. A wellbore can have portions that are vertical, horizontal, or anything in between, and it can have portions that are straight, curved, or branched. As used herein, “uphole,” “downhole,” and similar terms are relative to the direction of the wellhead, regardless of whether a wellbore portion is vertical or horizontal.

A wellbore can be used as a production or injection wellbore. A production wellbore is used to produce hydrocarbons from the reservoir. An injection wellbore is used to inject a fluid, for example, liquid water or steam, to drive oil or gas to a production wellbore.

Unless otherwise specified, use of the term “wellbore fluid” shall be construed as encompassing all fluids originating from within the wellbore and all fluids introduced or intended to be introduced into the wellbore. Accordingly, the term “wellbore fluid” encompasses, but is not limited to, formation fluids, production fluids, wellbore servicing fluids, the like, and any combinations thereof.

As used herein, introducing “into a well” means introducing at least into and through the wellhead. According to various techniques known in the art, tubulars, equipment, tools, or fluids can be directed from the wellhead into any desired portion of the wellbore.

As used herein, the word “tubular” means any kind of structural body in the general form of a tube. Tubulars can be of any suitable body material, but in the oilfield they are most commonly of metal, most commonly of steel. Examples of tubulars in oil wells include, but are not limited to, a drill pipe, a casing, a tubing string, a liner pipe, and a transportation pipe.

As used herein, the word “treatment” refers to any treatment for changing a condition of a portion of a pipeline, a wellbore, or a subterranean formation adjacent a wellbore; however, the word “treatment” does not necessarily imply any particular treatment purpose. A treatment usually involves introducing a fluid for the treatment, in which case it may be referred to as a treatment fluid, into a well. As used herein, a “treatment fluid” is a fluid used in a treatment. The word “treatment” in the term “treatment fluid” does not necessarily imply any particular treatment or action by the fluid.

In the context of a well or wellbore, a “portion” or “interval” refers to any downhole portion or interval along the length of a wellbore.

A “zone” refers to an interval of rock along a wellbore that is differentiated from uphole and downhole zones based on hydrocarbon content or other features, such as permeability, composition, perforations or other fluid communication with the wellbore, faults, or fractures. A zone of a wellbore that penetrates a hydrocarbon-bearing zone that is capable of producing hydrocarbon is referred to as a “production zone.” A “treatment zone” refers to a zone into which a fluid is directed to flow from the wellbore. As used herein, “into a treatment zone” means into and through the wellhead and, additionally, through the wellbore and into the treatment zone.

### Pipelines

As used herein, the word “tubular” means any kind of structural body in the general form of a tube. Tubulars can be of any suitable body material, but in the oilfield they are most commonly of metal, most commonly of steel. Tubulars can be used to transport fluids such as oil, gas, water, liquefied methane, coolants, and heated fluids into or out of a subterranean formation. For example, a tubular can be placed underground to transport produced hydrocarbons or water from a subterranean formation to another location.

“Pipeline transport” refers to a conduit made from pipes connected end-to-end for long-distance fluid transport. Oil pipelines are made from steel or plastic tubulars with inner diameter typically from 4 to 48 inches (100 to 1,200 mm). Most pipelines are typically buried at a depth of about 3 to 6 feet (0.91 to 1.8 m). To protect pipes from impact, abrasion, and corrosion, a variety of methods are used. These can include wood lagging (wood slats), concrete coating, rockshield, high-density polyethylene, imported sand padding, and padding machines. The oil is kept in motion by pump stations along the pipeline, and usually flows at speed of about 3.3 to 20 ft/s (1 to 6 meters per second).

Gathering pipelines are a group of smaller interconnected pipelines forming complex networks with the purpose of bringing crude oil or natural gas from several nearby wells to a treatment plant or processing facility. In this group, pipelines are usually relatively short (usually about 100 to 1000 yards or meters) and with small diameters (usually about 4 to about 12 inches). Also sub-sea pipelines for collecting product from deep water production platforms are considered gathering systems.

Transportation pipelines are mainly long pipes (many miles or kilometers) with large diameters (larger than 12 inches or 30 cm), moving products (oil, gas, refined products) between cities, countries, and even continents. These transportation networks include several compressor stations in gas lines or pump stations for crude oil or multi-product pipelines.

Distribution pipelines are composed of several interconnected pipelines with small diameters (usually about 1 to about 4 inches), used to take the products to the final consumer. An example of distribution pipelines is feeder lines to distribute natural gas to homes and businesses downstream. Pipelines at terminals for distributing products to tanks and storage facilities are included in this group.

A “portion” or “interval” of a pipeline refers to any portion of the length of a pipeline.

### Substances, Phases, Physical States, and Materials

A substance can be a pure chemical or a mixture of two or more different chemicals. A pure chemical is a sample of matter that cannot be separated into simpler components without chemical change.

As used herein, “phase” is used to refer to a substance having a chemical composition and physical state that is distinguishable from an adjacent phase of a substance having a different chemical composition or a different physical state.

The word “material” refers to the substance, constituted of one or more phases, of a physical entity or object. Rock, water, air, metal, cement slurry, sand, and wood are all examples of materials. The word “material” can refer to a single phase of a substance on a bulk scale (larger than a particle) or a bulk scale of a mixture of phases, depending on the context.

As used herein, if not other otherwise specifically stated or the context otherwise requires, the physical state or phase of a substance (or mixture of substances) and other physical properties are determined at a temperature of 77° F. (25° C.) and a pressure of 1 atmosphere (Standard Laboratory Conditions) without applied shear.

### Particles and Particulates

As used herein, a “particle” refers to a body having a finite mass and sufficient cohesion such that it can be considered as an entity but having relatively small dimensions. A particle can be of any size ranging from molecular scale to macroscopic, depending on context.

A particle can be in any physical state. For example, a particle of a substance in a solid state can be as small as a few molecules on the scale of nanometers up to a large particle on the scale of a few millimeters, such as large grains of sand. Similarly, a particle of a substance in a liquid state can be as small as a few molecules on the scale of nanometers up to a large drop on the scale of a few millimeters. A particle of a substance in a gas state is a single atom or molecule that is separated from other atoms or molecules such that intermolecular attractions have relatively little effect on their respective motions.

As used herein, particulate or particulate material refers to matter in the physical form of distinct particles in a solid or liquid state (which means such an association of a few atoms or molecules). As used herein, a particulate is a grouping of particles having similar chemical composition and particle size ranges anywhere in the range of about 10 nanometer to about 3 millimeters, for example, large grains of sand.

A particulate can be of solid or liquid particles. As used herein, however, unless the context otherwise requires, particulate refers to a solid particulate. Of course, a solid particulate is a particulate of particles that are in the solid physical state, that is, the constituent atoms, ions, or molecules are sufficiently restricted in their relative movement to result in a fixed shape for each of the particles.

It should be understood that the terms “particle” and “particulate,” includes all known shapes of particles including substantially rounded, spherical, oblong, ellipsoid, rod-like, fiber, polyhedral (such as cubic materials), etc., and mixtures thereof. For example, the term “particulate” as used herein is intended to include solid particles having the physical shape of platelets, shavings, flakes, ribbons, rods, strips, spheroids, toroids, pellets, tablets or any other physical shape.

As used herein, a fiber is a particle or grouping of particles having an aspect ratio L/D greater than 5/1.

### Fluids

A fluid can be a homogeneous or heterogeneous. In general, a fluid is an amorphous substance that is or has a continuous phase of particles that are smaller than about 1 micrometer that tends to flow and to conform to the outline of its container.

Examples of fluids are gases and liquids. A gas (in the sense of a physical state) refers to an amorphous substance that has a high tendency to disperse (at the molecular level) and a relatively high compressibility. A liquid refers to an amorphous substance that has little tendency to disperse (at the molecular level) and relatively high incompressibility. The tendency to disperse is related to Intermolecular Forces (also known as van der Waal's Forces). (A continuous mass of a particulate, for example, a powder or sand, can tend to flow as a fluid depending on many factors such as particle size distribution, particle shape distribution, the proportion and nature of any wetting liquid or other surface coating on the particles, and many other variables. Nevertheless, as used herein, a fluid does not refer to a continuous mass of particulate as the sizes of the solid particles of a mass of a particulate are too large to be appreciably affected by the range of Intermolecular Forces.)

Every fluid inherently has at least a continuous phase. A fluid can have more than one phase. For example, a fluid can be in the form of a suspension (larger solid particles dispersed in a liquid phase), a sol (smaller solid particles dispersed in a liquid phase), or an emulsion (liquid particles dispersed in another liquid phase).

### General Approach

This disclosure provides materials for coating a surface that can be used to control the growth rate and morphology of inorganic crystals such as scale. The material promotes the growth of nanodendritic crystal structures to reduce the buildup of scale on various types of surfaces in a well or pipeline.

In various embodiments, methods include the use of a applying the coating material according to the disclosure to create a surface that promotes the production of inert microcrystal scale, which will under fluid flow shear break off into nano-sized particulates and not remain deposited/adhered to the surface, thus dramatically reducing the rate of scale deposition on the surface. The methods lead to long-term scale prevention in a well or pipeline. In various embodiments, a coating material according to the disclosure can be used in a well or pipeline for the seeding of inorganic crystals of materials such as barium sulfate, calcium sulfate, ferrous, ferrite, phosphate, silicate, and other scale forming ion combinations that may be present in a fluid in a well or pipeline.

In various embodiments, the coating material can be incorporated onto a metallic surface of tubing in a wellbore or as part of a pipeline to prevent the buildup of scale on the surface, which scale would restrict fluid flow adjacent to the surface. In various embodiments, the coating material can be used to coat a metallic surface of a tubular.

Scale-forming ions may include, for example, barium ions, calcium ions, magnesium ions, strontium ions, manganese ions aluminum ions, sulfate ions, ferrous ions, ferrite ions, phosphate ions, silicate, hydrogen carbonate ions, carbonate ions, sodium ions, or any combination thereof.

Relatively large amounts of fluid (e.g., water) may be needed for the preparation of wellbore servicing fluids, such as drilling fluid, completion fluid, clean-out fluids, cementitious slurries, stimulation fluids (for example, fracturing or perforating fluids), acidizing fluids, gravel-packing fluids, or the like. Common fluid sources used for preparing wellbore servicing fluids include surface water, municipal water, and water co-produced in the production of oil and gas, hereinafter referred to as produced water. Water obtained from one or more of such sources may contain concentrations of dissolved scale-forming ions. A fluid containing concentrations of dissolved scale-forming ions may adversely affect the intended function of a wellbore servicing fluid formed therefrom and may contribute to the degradation or failure of wellbore servicing equipment in contact with the fluid, such as through corrosion or the formation of scale (e.g., in the form of calcium, magnesium carbonates, and other scale-forming ions) on flow surfaces of such wellbore servicing equipment. Further, concentrations of such scale-forming ions may adversely affect the intended function of a wellbore servicing fluid or render the fluid unusable for use in wellbore servicing operations or for use in the production of a wellbore servicing fluid.

### Vapor Depositing a Source Material Comprising Metal Oxides

Vapor deposited metal oxides, such as ZnO, ZrO, SnO₂, CuO, TiO₂, Li₂O, and any combination thereof can be deposited onto a surface. In various embodiments, the source material is mixed with graphite.

For example, using solid-vapor phase thermal sublimation techniques, nanocombs, nanorings, nanohelixes, nanosprings, nanobelts, nanowires, and nanocages of ZnO have been synthesized under specific growth conditions. See, Zhong Lin Wang, Zinc oxide nanostructures: growth, properties and applications, J. Phys.: Condens. Matter 16 (2004) R829-R858.

It is known that some metal oxides, such as ZnO, decompose when subjected to high enough temperature in vacuum, which can occur under some vapor deposition conditions. See, Zhong Lin Wang, Zinc oxide nanostructures: growth, properties and applications, J. Phys.: Condens. Matter 16 (2004) R829-R858.

In general, all such nano structures have one or more solid portions, each portion having a length (that is, a longest dimension), wherein all the smaller dimensions of the structure (such as diameter, width, or thickness) are less than about 500 nm. In addition, the morphology of these structures depends on the synthetic pathway and the chemical constituents used in production of these materials. Of course, the overall structure, such as the length of a belt or the open space of a helix, spring, ring, or cage structure can be much larger. Nevertheless, the structures are relatively delicate and considered to be on a nano-scale.

These materials and methods (vapor deposited metal oxides) reduce the need for production-side scale inhibitors.

Enables scale prevention as a part of well development strategy, as squeeze radial treatment for scale is not feasible in low permeability reservoirs.

Reduces the need for additional chemicals, improves the environmental sustainability of the service company or the operator.

Provides long-term scale prevention on surfaces of metallic bodies, such as tubulars used for making up downhole tubing strings or transportation pipelines.

### Discussion

The vapor-deposited material according the disclosure is believed to be effective to reduce the concentration of dissolved multivalent ions, such as hard ions (e.g., calcium ions, magnesium ions, iron ions, strontium ions, manganese ions, aluminum ions, sulfate ions, hydrogen carbonate ions, carbonate ions, etc.) present within a solution or composition.

Not intending to be bound by theory, the surface morphology of the coated surface is believed to comprise a great number of nucleation sites that can contribute to the formation of crystals over the coated surface.

Without being bound by any theory, the vapor-deposited material is configured to convert dissolved multivalent ions into inert crystalline solids. For example, not intending to be bound by theory, the vapor-deposited material can act as a site for heterogeneous nucleation. For example, the surface geometry of the vapor-deposited material can provide a lower energy path for the formation of a crystalline solid from a plurality of multivalent (e.g., divalent) ions through the process of nucleation. During nucleation on such a vapor-deposited material on a surface, a nucleus of solute molecules (e.g., multivalent ions) is formed and reaches a critical size so as to stabilize within the solvent. Not intending to be bound by theory, once a nucleus has reached the critical size, where the crystalline structure has begun to form, crystal growth of the nucleus may continue until the size of the forming crystal reaches a point where it breaks free from the vapor-deposited (nano dendritic surface) material on the surface. Once the crystal (e.g., an inert crystalline solid) has broken free from the template, it may continue absorbing other dissolved ions within the solvent, acting as a site for homogenous nucleation. Not intending to be bound by theory, crystals formed from the vapor-deposited material on a surface can be kept in the fluid stream, and with their presence, can further accelerate the conversion of dissolves ions into crystals within the fluid stream. As such, the vapor-deposited surface can aid in converting dissolved multivalent ions into inert crystalline solids, which may be less than 500 nm in size, which can be carried in the fluid without accumulating as scale on surfaces in a well or pipeline.

### EXAMPLES

To facilitate a better understanding of the present disclosure, the following examples of certain aspects of some embodiments are given. In no way should the following examples be read to limit, or define, the entire scope of the disclosure.

### Well Operating Environment and System

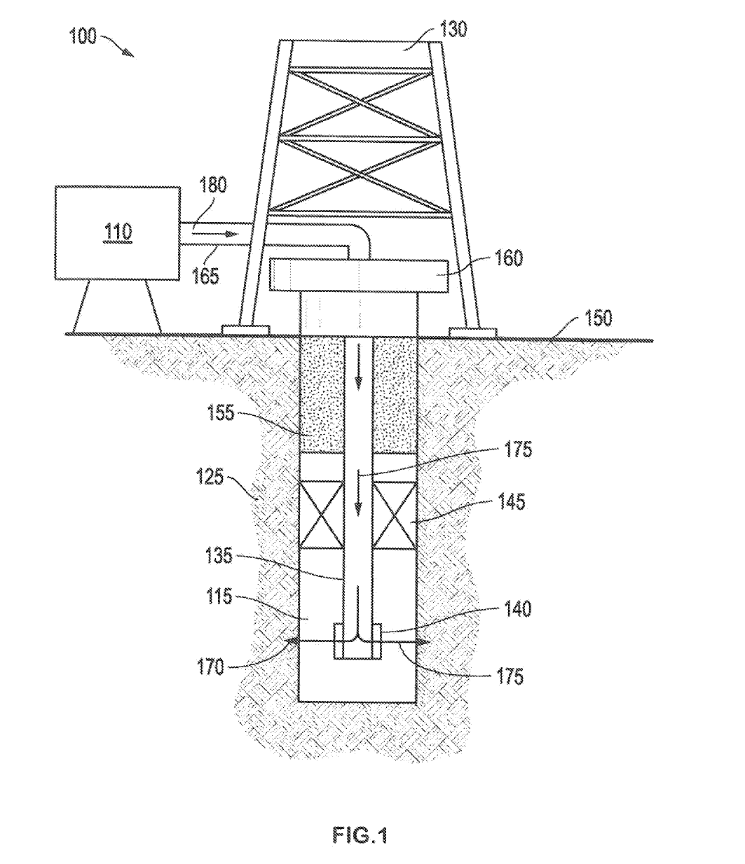

FIG. 1 schematically illustrates a well operating environment and system. In the embodiment of FIG. 1, such an operating environment comprises a well site 100 including a wellbore 115 penetrating a subterranean formation 125 for the purpose of recovering hydrocarbons, storing hydrocarbons, disposing of carbon dioxide, injecting wellbore servicing fluids, or the like.

A surface wellbore fluid treatment (SWFT) system 110 for the treatment of a wellbore servicing fluid (WSF) or a component thereof (for example, water) can be deployed at the well site 100 and is fluidly coupled to the wellbore 115 via a wellhead 160.

The wellbore 115 can be drilled into the subterranean formation 125 using any suitable drilling technique. In an embodiment, a drilling or servicing rig 130 can generally comprise a derrick with a rig floor through which a tubular string 135 (e.g., a drill string; a work string, such as a segmented tubing, coiled tubing, jointed pipe, or the like; a casing string; or combinations thereof) may be lowered into the wellbore 115.

A wellbore servicing apparatus 140 configured for one or more wellbore servicing operations (for example, a cementing or completion operation, a clean-out operation, a perforating operation, a fracturing operation, production of hydrocarbons, etc.) can be integrated with or at the end of the tubular string 135 for performing one or more wellbore servicing operations. For example, the wellbore servicing apparatus 140 may be configured to perform one or more servicing operations, for example, fracturing the formation 125, hydrajetting or perforating casing (when present) or the formation 125, expanding or extending a fluid path through or into the subterranean formation 125, producing hydrocarbons from the formation 125, or other servicing operation. In an embodiment, the wellbore servicing apparatus 140 may comprise one or more ports, apertures, nozzles, jets, windows, or combinations thereof suitable for the communication of fluid from a flowpath of the tubular string 135 or a flowpath of the wellbore servicing apparatus 140 to the subterranean formation 125. In an embodiment, the wellbore servicing apparatus 140 is actuatable (for example, openable or closable), for example, comprising a housing comprising a plurality of housing ports and a sleeve being movable with respect to the housing, the plurality of housing ports being selectively obstructed or unobstructed by the sliding sleeve so as to provide a fluid flowpath to or from the wellbore servicing apparatus 140 into the wellbore 115, the subterranean formation 125, or combinations thereof. In an embodiment, the wellbore servicing apparatus 140 may be configurable for the performance of multiple wellbore servicing operations.

Additional downhole tools can be included with or integrated within the wellbore servicing apparatus 140 or the tubular string 135, for example, one or more isolation devices 145 (for example, a packer, such as a swellable or mechanical packer) may be positioned within the wellbore 115 for the purpose of isolating a portion of the wellbore 115.

The drilling or servicing rig 130 can be conventional and can comprise a motor-driven winch and other associated equipment for lowering the tubular string 135 or wellbore servicing apparatus 140 into the wellbore 115. Alternatively, a mobile workover rig, a wellbore servicing unit (e.g., coiled tubing units), or the like may be used to lower the tubular string 135 or wellbore servicing apparatus 140 into the wellbore 115 for performing a wellbore servicing operation.

The wellbore 115 may extend substantially vertically away from the earth's surface 150 over a vertical wellbore portion, or may deviate at any angle from the earth's surface 150 over a deviated or horizontal wellbore portion. Alternatively, portions or substantially all of the wellbore 115 may be vertical, deviated, horizontal, or curved.

In various embodiments, the tubular string 135 may comprise a casing string, a liner, a production tubing, coiled tubing, a drilling string, the like, or combinations thereof. The tubular string 135 may extend from the earth's surface 150 downward within the wellbore 115 to a predetermined or desirable depth, for example, such that the wellbore servicing apparatus 140 is positioned substantially proximate to a portion of the subterranean formation 125 to be serviced (for example, into which a fracture 170 is to be introduced).

In some instances, a portion of the tubular string 135 can be secured into position within the wellbore 115 in a conventional manner using cement 155; alternatively, the tubular string 135 may be partially cemented in wellbore 115; alternatively, the tubular string 135 may be uncemented in the wellbore 115.

In an embodiment, the tubular string 135 can comprise two or more concentrically positioned strings of pipe (for example, a first pipe string such as jointed pipe or coiled tubing may be positioned within a second pipe string such as casing cemented within the wellbore).

In an embodiment, the SWFT system 110 can be coupled to the wellhead 160 via a conduit 165, and the wellhead 160 may be connected (for example, fluidly) to the tubular string 135. Flow arrows 180 and 175 indicate a route of fluid communication from the SWFT system 110 to the wellhead 160 via conduit 165, from the wellhead 160 to the wellbore servicing apparatus 140 via tubular string 135, and from the wellbore servicing apparatus 140 into the wellbore 115 or into the subterranean formation 125 (for example, into fractures 170).

It should be understood, of course, that during production of fluid from the subterranean formation, the fluid flows in the reverse direction from the subterranean formation 125, through a wellbore servicing apparatus 140, through tubular string 135, to the wellhead 160, and out via a conduit, such as conduit 165, and beyond.

Although one or more of the figures may exemplify a given operating environment, the principles of the devices, systems, and methods disclosed can be similarly applicable in other operational environments, such as offshore or subsea wellbore applications.

### Pipeline Operating Environment

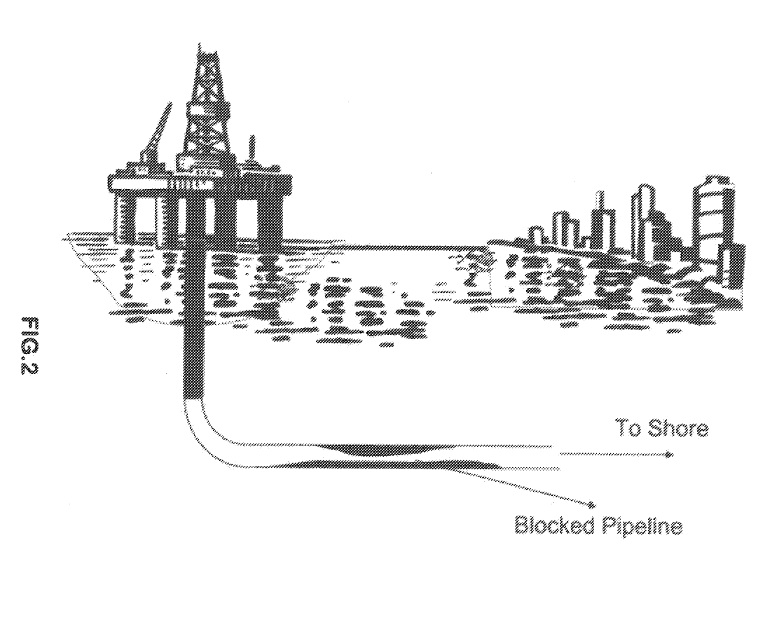

As the scale deposits build up on the inside wall of a conduit, the opening for fluid flow through the pipeline becomes smaller and smaller. Unless at least some of the buildup is removed from time to time, eventually the scale deposits can increase to the point where the conduit becomes choked. This scale formation leads to reduced crude oil flow and under extreme conditions leads to complete blockage of a pipeline, for example, as illustrated in FIG. 2.

### Example of Vapor-Deposition Equipment and Techniques

The thermal evaporation and deposition technique is a simple process in which a condensed or powder source material is vaporized using at least a sufficiently high temperature and the resultant vapor phase condenses under appropriate conditions of temperature, pressure, atmosphere, substrate, etc., as known in such technologies to form a desired vapor-deposited material on a substrate.

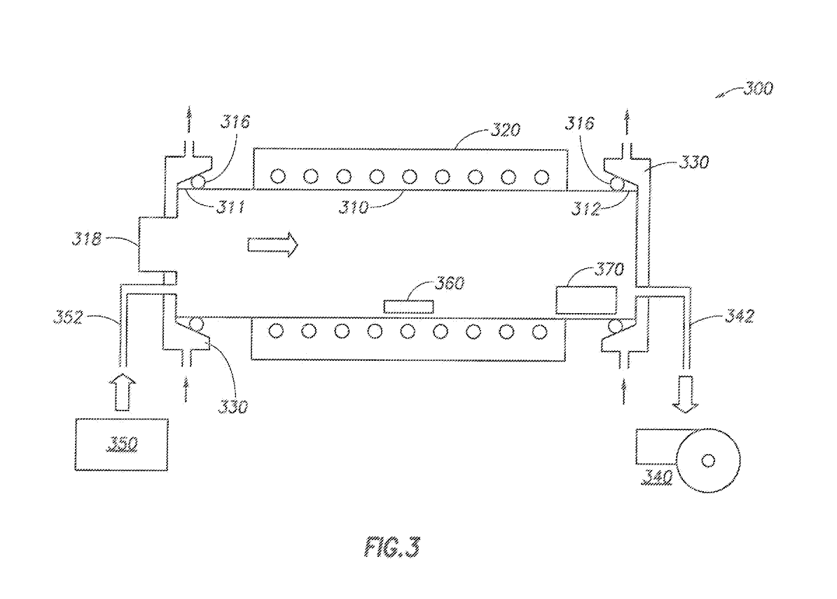

An example of a vapor-deposition furnace 300 is illustrated in FIG. 3, which includes a horizontal alumina tube 310 having a first end 311 and a second end 312. The first end 311 and second end 312 can be closed to form a chamber 314. At least one of the ends of the horizontal tube 310 is adapted to be selectively opened and closed to access the chamber 314. Both ends both ends 311 and 312 of the horizontal alumina tube 310 are sealed by rubber O-rings 316. An optional window 318 can be set up at an end 311 or 312 of the horizontal alumina tube 310, which can be used to view a vapor-deposition process in the chamber 314.

A furnace 320 is operatively positioned adjacent the exterior of the horizontal alumina tube 310 for heating the alumina tube 310 and the chamber 314.

A cooling system 330 is operatively connected at both ends 311 and 312 of the horizontal alumina tube 310.

A vacuum pump 340 is operatively connected through conduit 342 to and through the second end 312 into the chamber 314 of the horizontal alumina tube 310. The vacuum pump 340 can pump the chamber 314 of the horizontal tube furnace 310 to a low vacuum, preferably as low as about 2×10⁻³ Torr.

A carrier gas supply 350 is operatively connected through conduit 352 to and through the first end 311 into the chamber 314 of the horizontal alumina tube 310. The carrier gas is preferably an inert gas, such as argon (Ar).

A control system (not shown) is provided for the operation of the vapor-deposition furnace 300, including for the control of the furnace 320, the cooling system 330, the vacuum pump 340, and the flow of the carrier gas from the carrier gas supply 350.

In operation, when an end 311 or 312 of the chamber 314 is opened, a source material, such as ZrO powder, can be placed in a boat 360 in the chamber 314 of the horizontal alumina tube 310. The boat 360 is preferably located or positioned at about the center of the chamber 314 in the horizontal alumina tube 310 where the temperature can be the highest. In addition, one or more products 370 to be treated or coated with vapor-deposition can be place in the chamber 314 adjacent the second end 312. The chamber 314 can then be closed.

The furnace 320 can be operated and controlled to heat the alumina tube 310 and chamber 314 to a high temperature required for vaporizing a source material, such as ZnO powder.

The cooling system 330 can be operated and controlled to keep the portions adjacent the first end 311 and second end 312 inside the chamber 314 of the horizontal alumina tube 310 relatively cooler than a center portion of the chamber 314.

The vacuum pump 340 can be operated and controlled to reduce the pressure inside the chamber.

The carrier gas supply 350 can be operated and controlled to release a carrier gas, such as Ar, to be introduced into the chamber 314 at a desired rate. Due to the operation of the vacuum pump 340, the carrier gas will move as a stream 355 through the chamber 314 from adjacent the first end 311 to adjacent the second end 312. The stream 355 also entrains and moves newly vaporized source material with the stream 355.

In operation, as the source material is vaporized, it is entrained with the carrier gas stream 355 and moves to a cooler portion of the chamber 314 adjacent the second end 312. Due to the relatively lower temperature, some of the vaporized source material can be deposited onto exposed surfaces of the product 370.

This simple set-up can achieve high control of the vapor-deposition on exposed surfaces of the product 370.

Controlling the process parameters such as chamber temperature, pressure, carrier gas (including gas species and its flow rate), substrate surface of the product, and evaporation time can help control the morphology of the vapor-deposited material.

The temperature control for the center of the horizontal furnace mainly depends on the volatility of the source materials. Usually, it is slightly lower than the melting point of the source material.

The pressure in the chamber is determined according to the evaporation rate or vapor pressure of the source material(s).

The substrate temperature of the product 370 is lower than the highest temperature at the center of the chamber 314. The local temperature of the product 370 helps control the type of morphology of the vapor-deposited material on a surface of the product.

The vapor-deposition process can be very sensitive to the concentration of oxygen in the growth system. Oxygen influences not only the volatility of the source material and the stoichiometry of the vapor phase, but also the formation of the product.

The deposited products can be characterized and analyzed by one or more of various techniques such as x-ray diffraction (XRD), scanning electron microscopy (SEM), transmission electron microscopy (TEM), and energy dispersive x-ray spectroscopy (EDS), which are known in such fields.

Additional information regarding such vapor-deposition furnaces and techniques for their use is disclosed in Zhong Lin Wang, Zinc oxide nanostructures: growth, properties and applications, J. Phys.: Condens. Matter 16 (2004) R829-R858.

It should be understood that a vapor-deposition furnace can be made in various configurations and sizes. In a manufacturing process, such equipment can be made to an appropriate scale to accommodate a body to be treated or coated with the desired vapor-deposited material.

### Graphical Representation of Processes in a Tubular

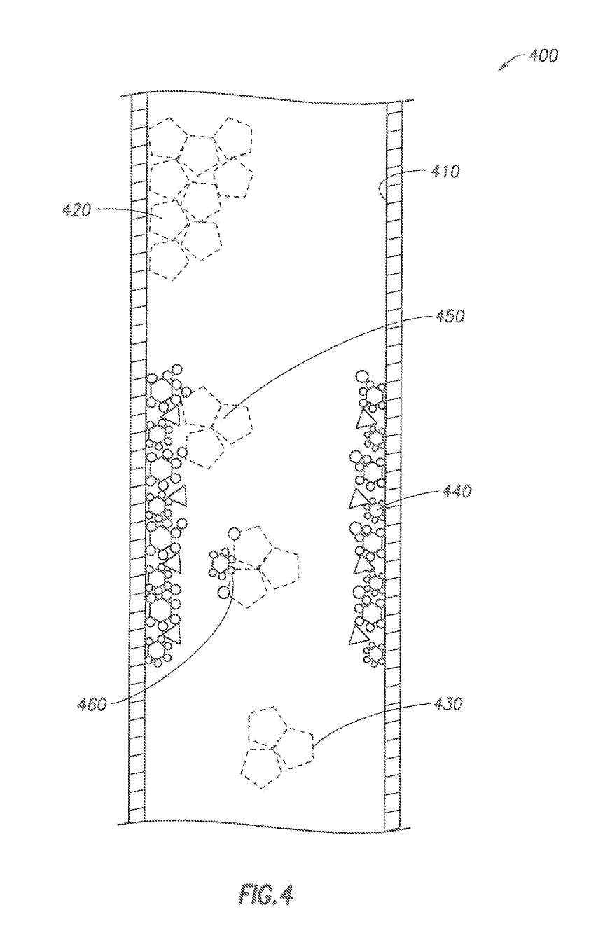

FIG. 4 is an cross-sectional illustration of a length of a tubular 400, such as downhole in a well or part of a pipeline, having an inner wall surface 410, graphically representing:
(a) a typical precipitation and accumulation of scale 420 from scale-forming ions on the inner wall surface 410;
(b) precipitation of mineral particulates 430 from a fluid in the tubular 400;
(b) vapor-deposited material forming nano-structures 440 on another region of the inner wall surface 410,
(c) precipitation of mineral material 450 from scale-forming ions onto the nano-structures of the vapor-deposited material; and
(d) breaking-off of nano-sized pieces 460 comprising scale precipitated onto the fragile nano-structures of the vapor-deposited material.

### Conclusion

Therefore, the present disclosure is well adapted to attain the ends and advantages mentioned as well as those that are inherent therein.

The exemplary vapor-deposited materials disclosed herein may directly or indirectly affect one or more components or pieces of equipment associated with the preparation, delivery, recapture, recycling, reuse, or disposal of the disclosed vapor-deposited materials. For example, the disclosed vapor-deposited materials may directly or indirectly affect one or more mixers, related mixing equipment, mud pits, storage facilities or units, fluid separators, heat exchangers, sensors, gauges, pumps, compressors, and the like used generate, store, monitor, regulate, or recondition the exemplary vapor-deposited materials. The disclosed vapor-deposited materials may also directly or indirectly affect any transport or delivery equipment used to convey the vapor-deposited materials to a well site or downhole such as, for example, any transport vessels, conduits, pipelines, trucks, tubulars, or pipes used to fluidically move the vapor-deposited materials from one location to another, any pumps, compressors, or motors (for example, topside or downhole) used to drive the vapor-deposited materials into motion, any valves or related joints used to regulate the pressure or flow rate of the vapor-deposited materials, and any sensors (i.e., pressure and temperature), gauges, or combinations thereof, and the like. The disclosed vapor-deposited materials may also directly or indirectly affect the various downhole equipment and tools that may come into contact with the vapor-deposited materials such as, but not limited to, drill string, coiled tubing, drill pipe, drill collars, mud motors, downhole motors or pumps, floats, MWD/LWD tools and related telemetry equipment, drill bits (including roller cone, PDC, natural diamond, hole openers, reamers, and coring bits), sensors or distributed sensors, downhole heat exchangers, valves and corresponding actuation devices, tool seals, packers and other wellbore isolation devices or components, and the like.

The particular embodiments disclosed above are illustrative only, as the present disclosure may be modified and practiced in different but equivalent manners apparent to those skilled in the art having the benefit of the teachings herein. It is, therefore, evident that the particular illustrative embodiments disclosed above may be altered or modified and all such variations are considered within the scope of the present disclosure.

The various elements or steps according to the disclosed elements or steps can be combined advantageously or practiced together in various combinations or sub-combinations of elements or sequences of steps to increase the efficiency and benefits that can be obtained from the disclosure.

It will be appreciated that one or more of the above embodiments may be combined with one or more of the other embodiments, unless explicitly stated otherwise.

The illustrative disclosure can be practiced in the absence of any element or step that is not specifically disclosed or claimed.

Furthermore, no limitations are intended to the details of construction, composition, design, or steps herein shown, other than as described in the claims.

What is claimed is:

1. A method of protecting a surface of a metallic body against scale formation in a well, the method comprising:
vapor depositing a source material comprising a metal oxide onto the surface of the metallic body; and
positioning the metallic body in a wellbore of a well.

2. The method according to claim 1, additionally comprising:
flowing a fluid across the surface of the metallic body in the well, wherein the fluid comprises scale-forming ions.

3. A well system comprising:
a wellbore; and
a metallic body positioned in the wellbore, wherein a surface of the metallic body has a coating produced by vapor depositing a source material comprising a metal oxide onto the surface.

4. The well system according to claim 3, additionally comprising a fluid in the wellbore, wherein the fluid comprises scale-forming ions.

5. A method of protecting a surface of a metallic body against scale formation in a pipeline, the method comprising:
vapor depositing a source material comprising a metal oxide onto the surface of the metallic body; and
positioning the metallic body to form a portion of a pipeline.

6. The method according to claim 5, additionally comprising:
flowing a fluid across the surface of the metallic body in the pipeline, wherein the fluid comprises scale-forming ions.

7. A pipeline system comprising:
a metallic body positioned to form a portion of the pipeline, wherein a surface of the metallic body exposed to the interior fluid flowpath of the pipeline has a coating produced by vapor depositing a source material comprising a metal oxide onto the surface.

8. The pipeline system according to claim 7, additionally comprising: a fluid in the pipeline, wherein the fluid comprises scale-forming ions.

9. The method according to claim 1, wherein the metal oxide is selected from the group consisting of: ZnO, ZrO, SnO₂, CuO, TiO₂, Li₂O, and any combination thereof.

10. The method according to claim 9, wherein the source material additionally comprises graphite.

11. The well system according to claim 3, wherein the metallic body is a tubular.

12. The well system according to claim 11, wherein the surface is at least a portion of an inner wall of the tubular.

13. The method according to claim 1, wherein vapor depositing is accomplished in a vapor deposition furnace.

14. The method according to claim 13, wherein vapor depositing is accomplished by:
(a) placing the source material in a chamber of the vapor deposition furnace;
(b) placing the metallic body in the chamber;
(c) heating the chamber to a temperature at least sufficient to vaporize at least the metal oxide of the source material;
(d) pumping an atmosphere from the chamber of the vapor deposition furnace to reduce the pressure in the chamber; and
(e) flowing a stream of a carrier gas through the chamber across the source material to the metallic body, whereby vaporized metal oxide is carried and deposited onto the surface of the metallic body.

15. The well system according to claim 3, wherein the metallic body is a tubular, and the positioning or position of the metallic body forms a portion of a tubular string providing a flowpath through the tubular string.

16. The method according to claim 2, wherein the scale-forming ions are selected from the group consisting of: calcium, magnesium, barium, strontium, sulfate, carbonate, bicarbonate, ferrous, ferrite, phosphate, silicate, and any combination thereof.

17. The well system according to claim 3, wherein the metal oxide is selected from the group consisting of: ZnO, ZrO, SnO₂, CuO, TiO₂, Li₂O, and any combination thereof;
and wherein the source material additionally comprises graphite.

18. The well system according to claim 3, wherein the metallic body is a tubular, wherein the surface is at least a portion of an inner wall of the tubular, and wherein the tubular is positioned to form a portion of a tubular string providing a flowpath through the tubular string.

19. The method according to claim 5, wherein vapor depositing is accomplished by:
(a) placing the source material in a chamber of a vapor deposition furnace;
(b) placing the metallic body in the chamber;
(c) heating the chamber to a temperature at least sufficient to vaporize at least the metal oxide of the source material;
(d) pumping an atmosphere from the chamber of the vapor deposition furnace to reduce the pressure in the chamber; and
(e) flowing a stream of a carrier gas through the chamber across the source material to the metallic body, whereby vaporized metal oxide is carried and deposited onto the surface of the metallic body

20. The pipeline system of claim 7, wherein the metal oxide is selected from the group consisting of: ZnO, ZrO, SnO₂, CuO, TiO₂, Li₂O, and any combination thereof; and
wherein the source material additionally comprises graphite.
